(19) United States
(12) Patent Application Publication
(10) Pub. No.: US 2007/0045766 A1
(43) Pub. Date: Mar. 1, 2007

(54) Conductive element and an electric connector using the same

(76) Inventor: Chien-Chih Ho, Keelung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/318,880

(22) Filed: Dec. 28, 2005

(30) Foreign Application Priority Data
Aug. 24, 2005 (CN) 200510036666.3

(51) Int. Cl. H01L 23/58

(52) U.S. Cl. 257/493

(57) ABSTRACT

A conductive element and an electric connector using the same, wherein the conductive element is formed by plating a thin metal layer on the surface of a liquid electric conductor. The electric connector comprises an insulating body and at least a conductive element contained therein, wherein the conductive elements are formed by plating the thin metal layer on the surface of the liquid electric conductor. The conductive element of the present invention has a liquid metal with low impedance to obviously reduce the impedance of the conductive element, and it plates the thin meal layer on the surface of the liquid electric conductor to increase the elasticity of the conductive element. Besides, the structure of the conductive element is simple to manufacture easily.

### BACKGROUND OF THE INVENTION

1. Field of the invention

The present invention relates to a conductive element and an electric connector using the same.

2. Description of the Prior Art

The conductive elements as the conductive terminals which are made by punching the sheetmetals have widely been used in the industry. The sheetmetals have high impedance in the touching location, especially while the conductive terminals connecting to the butt electronic elements. Besides, in order to obtain better elasticity of the conductive terminals and then to bend the conductive terminals, not only increasing the length of the conductive terminals but increasing the impedance of the conductive terminals and then to impair the performance of the electrical connector. However, under the long-term usage it causes the bent conductive terminals to be permanent deformed so as to be in abnormal condition. Also, it makes the structure of the conductive terminals more complicated.

Thus, the inventor of the present invention recognizes the above shortage should be corrected and special effort has been paid to research this field. The inventor intend to resolve the above problems with the invention of reasonable design and good effect.

### SUMMARY OF THE INVENTION

It is an objective of the present invention to provide a conductive element with low impedance, simple structure, and better elasticity, and an electric connector using the same.

For achieving the objective stated above, the conductive element is formed depends on plating the thin metal layer on the surface of the liquid electric conductor.

The electrical connector of the present invention, comprising an insulating body and at least a conductive element contained in the insulating body, wherein the conductive element is formed depends on plating the thin metal layer on the surface of the liquid electric conductor.

Comparing to the prior art, the conductive element of the present invention has a liquid metal with low impedance to obviously reduce the impedance of the conductive element, and plating the thin metal layer on the surface of the liquid electric conductor to increase the elasticity of the conductive element. Besides, the structure of the conductive element is to be manufactured simply and easily.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

FIG. 1 is a front view of a conductive element of the present invention;

FIG. 2 is a cross-sectional view of the conductive element illustrated in FIG. 1;

FIG. 3 is an assembled view of the conductive element and metals illustrated in FIG. 1;

FIG. 4 is an assembled view of the insulating bodies and the conductive elements of the electric connector to the present invention;

FIG. 5 is a partial enlarged view of the FIG. 4;

FIG. 6 is an assembled view of the insulating body and the fixed frame illustrated in FIG. 4;

FIG. 7 is a top, assembled view of the insulating body and the fixed frame illustrated in FIG. 6; and

FIG. 8 is an assembled view of the insulating body, fixed frame, pressing mechanism and the adsorbing cover illustrated in FIG. 6.

### DETAILED DESCRIPTION OF THE PREFERRED EMBODIMENTS

Advantages and features of the invention will be apparent from the following description, drawings and claims.

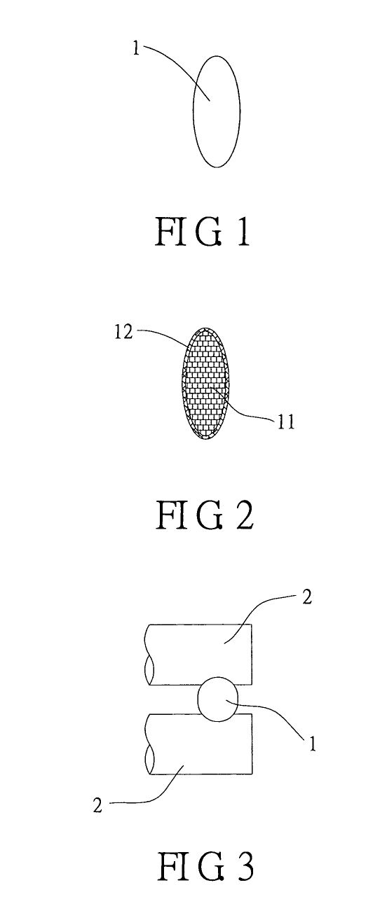

Reference is made to FIG. 1 to FIG. 3. A conductive element 1 comprises a liquid electric conductor 11 and a thin metal layer 12 plated thereon, and the conductive element 1 has been placed between two metals 2 to make the capability of electricity conduction.

The conductive element 1 comprises a liquid metal with low impedance (liquid electric conductor 11) to obviously reduce the impedance of the conductive element 1, and plates the thin metal layer 12 on the surface of the liquid metal to increase the elasticity of the conductive element. Besides, the structure of the conductive is simple to manufacture easily.

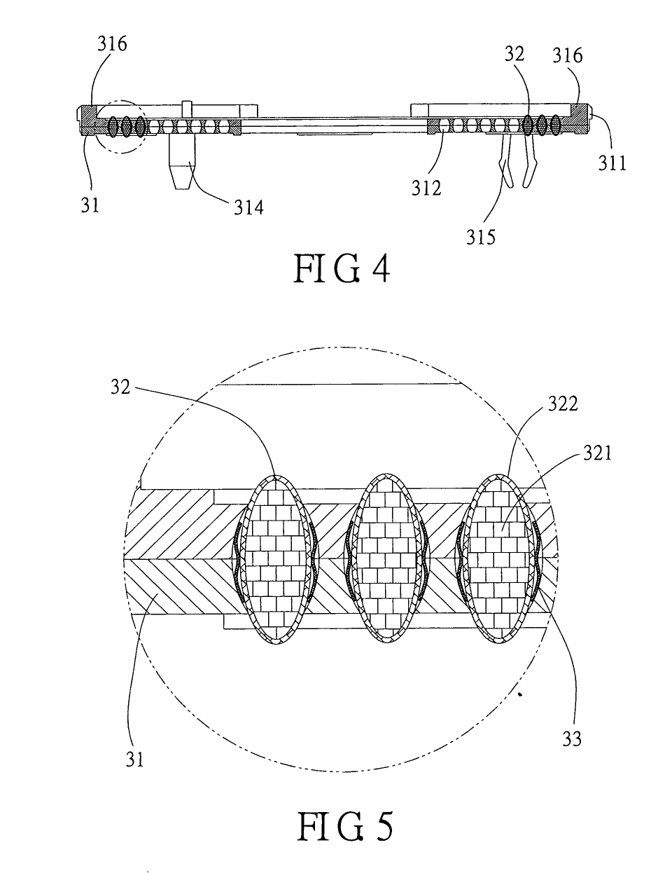

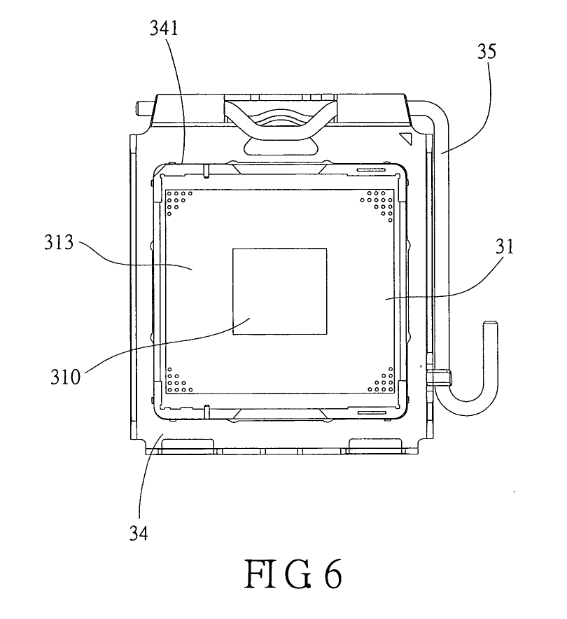

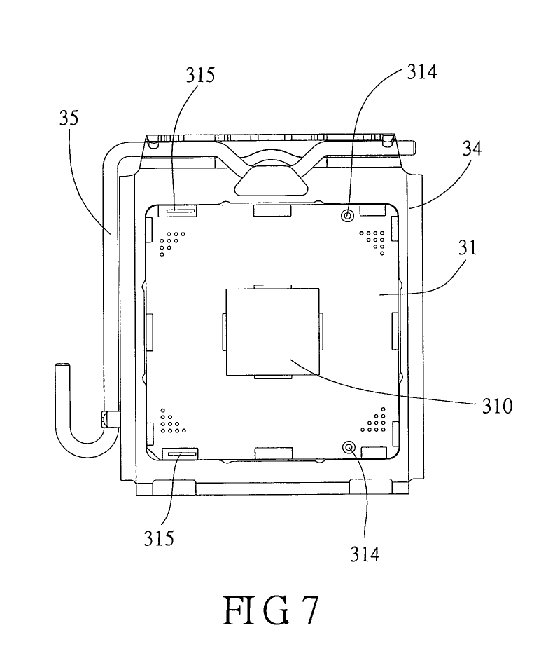

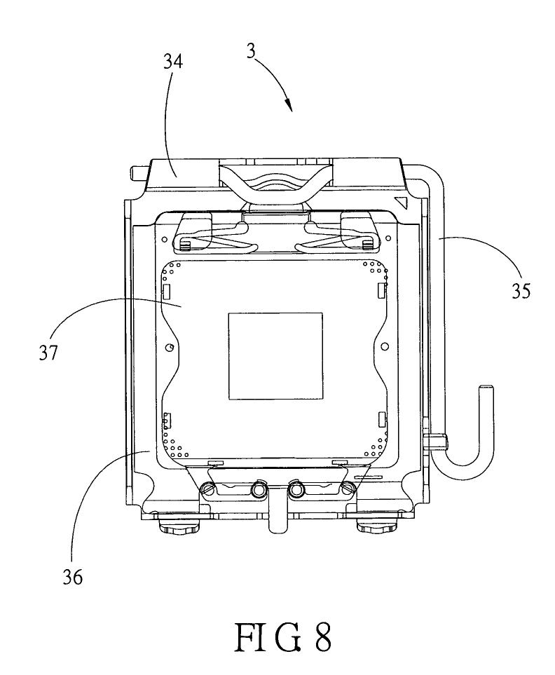

Reference is made from FIG. 4 to FIG. 8. An electrical connector 3, comprising an insulating body 31 and at least a conductive element 32 contained therein, is used to connect a circuit board (unshown) and a chip module (unshown). The insulating body 31 has one upper surface and one lower surface, and a square opening 310 placed in the center region of the insulating body 31; the four sides of the insulating body 31 have a plurality of protruded lumps 311. A plurality of containing holes 312 have been placed between the two surfaces, and the containing holes 312 passed through the two surfaces for containing the conductive elements 32. An annular elastic body 33 further has been contained in the containing holes 312 (the elastic body 33 may be a metal piece) to elastically compress the conductive elements 312 to make them have more flexible; a conductive area 313 placed within the insulating body 31 has containing holes 312. Besides, a locating mechanism placed in the insulating body 31, comprising two locating pillars 314 and two hooks 315 separately placed in two outsides of the conductive area 313 of the insulating body 31. The locating pillars 314 downward extended from the bottom surface of the insulating body 31; one end of the hooks 315 is disposed on the insulating body 31 and the other end protrude from the bottom surface of the insulating body 31. The electrical connector 3 disposed on the circuit board via the locating pillars 314 and the hooks 315(unshown). The locating mechanism further comprises locating frames 316, are disposed on the edges of the upper surface of the insulating body 31, for locating the butt chip module (butt electronic elements)(unshown) on the electrical connector 3.

The conductive element 32 is formed depends on plating a thin gold 322 on the surface of liquid mercury 321. The conductive elements 32 contained in the containing holes 312 of the insulating body 31, and the conductive elements 32 are protruding to the upper surface and lower surface of the insulating body 31.

The electrical connector 3 still further comprises a fixed frame 34 to fix the insulating body 31 thereon, and therefore the protruded lumps 311 of the insulating body 31 mutually lock with inner edges 341 of the fixed frame 34. Furthermore, a rocker 35 is disposed on the fixed frame 34 and a pressing mechanism 36 with a pressing butt chip module is disposed on the insulating body 31. The pressing mechanism 36 pivotly connected to one side of the fixed frame 34 to make them mutually connected, and the pressing mechanism 36 and the fixed frame 34 are pressed together while the rocker 35 is closed. An adsorbing cover 37 disposed on the pressing mechanism 36 for a nozzle (unshown) adsorbing thereon during the automatic installation process. The adsorbing cover 37 is made of a transparent or partial transparent material to make the square openings 310 of the insulating body 31 quickly aim at the corresponding position while the electrical connector 3 welding with the circuit board (unshown) so as to improve working efficiency.

While the electrical connector 3 connecting to the circuit board (unshown), the chip module (unshown) connects to the electrical connector 3. Hence, the chip module (unshown) directly disposed on the conductive area 313 of the insulating body 31, and the conductive elements 32 extended from the upper surface of the insulating body 31 can be connected to spacers (unshown) of the chip module. And, pressing the pressing mechanism 36 on the chip module and then closing the rocker 35 to firmly press the pressing mechanism 36 on the conductive area 313 of the insulating body 31 so as to achieve the electrical connection between the chip module and the circuit board.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A conductive element, which is formed by plating a thin metal layer on the surface of a liquid electric conductor.

2. An electrical connector, comprising an insulating body and at least a conductive element contained therein, wherein the conductive elements are formed depends on plating the thin metal layer on the surface of the liquid electric conductor.

3. The electrical connector as in claim 2, wherein the liquid electric conductor may be liquid mercury and the metal layer may be gold layer.

4. The electrical connector as in claim 2, wherein the insulating body at least has a containing hole and the conductive elements contained therein, and the insulating body having two surfaces and the containing hole of the insulating body passing through the two surfaces, and the conductive elements protruding to the two surfaces of the insulating body.

5. The electrical connector as in claim 4, wherein the containing hole comprising a elastic compressing body to elastically compress the conductive elements to make the conductive have more flexible.

6. The electrical connector as in claim 5, wherein the elastic compressing body is an annular elastic body.

7. The electrical connector as in claim 5, wherein the elastic compressing body is a metal piece.

8. The electrical connector as in claim 2, wherein the insulating body at least has a protruded locating mechanism to position the electrical connector and butt electronic elements.

9. The electrical connector as in claim 2, wherein the top of the insulating body has a pressing mechanism to press the butt electronic elements.

10. The electrical connector as in claim 9, wherein the pressing mechanism has an adsorbing cover for a nozzle adsorbing on the pressing mechanism.
